(19) United States
(12) Patent Application Publication
(10) Pub. No.: US 2015/0108444 A1
(43) Pub. Date: Apr. 23, 2015

(54) ORGANIC ELECTROLUMINESCENCE DEVICE AND DISPLAY APPARATUS

(71) Applicant: BOE TECHNOLOGY GROUP CO., LTD., Beijing (CN)

(72) Inventors: Zhiqiang Jiao, Beijing (CN); Li Sun, Beijing (CN)

(73) Assignee: BOE TECHNOLOGY GROUP CO., LTD., Beijing (CN)

(21) Appl. No.: 14/361,056

(22) PCT Filed: Nov. 14, 2013
(86) PCT No.: PCT/CN2013/087147

§ 371 Date: May 28, 2014

(30) Foreign Application Priority Data
May 21, 2013 (CN) 201310190495.4

(51) Int. Cl. H01L 51/50; H01L 51/52

(52) U.S. Cl. CPC H01L 51/5076; H01L 51/5206; H01L 51/0078
USPC 257/40

(57) ABSTRACT

An organic electroluminescence device is provided, including an anode, a cathode and a light emitting layer disposed between the anode and the cathode; an electron transport layer disposed between the cathode and the light emitting layer, a phthalocyanine dye being doped in the electron transport layer. A display apparatus including the organic electroluminescence device is also provided.

### TECHNICAL FIELD

Embodiments of the present invention relate to an organic electroluminescence device and a display apparatus.

### BACKGROUND

An organic light emitting device (abbreviated as OLED) consists of a cathode and an anode where a hole transport layer, a light emitting layer and an electron transport layer are disposed between the anode and the cathode. When a suitable voltage is applied between the cathode and the anode, holes generated by the anode and electrons generated by the cathode will be transported to the light emitting layer through the hole transport layer and the electron transport layer, respectively, and combined in the light emitting layer such that the light emitting layer emits lights. Due to different compositions in the light emitting layer, the light emitting layer can produce lights of three primary colors, namely, red, green and blue, which construct basic colors for display.

Research results show that, as electron mobility in the electron transport layer is low or energy barrier for electrons to be injected from the cathode to the electron transport layer is too high, amount of the electrons in the light emitting layer of the organic electroluminescence device is small, and amounts of the holes and of the electrons in the light emitting layer of the organic electroluminescence device are not matched, and amount of the holes is generally greater than amount of the electrons. Thus, light emitting efficiency of the organic electroluminescence device is low.

As to materials for the electron transport layer, from early used A1q₃ to Bphen commonly used later, electron injection capability thereof is improved continuously and effectively. However, with continuously improvement of organic light emitting material system and spreading of application field of organic electroluminescence devices, new requirements have been raised for brightness, efficiency, power consumption and manufacturing cost, and higher requirements are also raised for the cathode electron injection capability.

An organic electroluminescence device appears in recent years. Electron injection capability and electron transport capability in the organic electroluminescence device are improved by doping metal material such as lithium (Li) or cesium (Cs) into Bphen of the electron transport layer. However, as the metal material has a relative high diffusibility, a quenching center will appear in the light emitting layer if the metal material diffuses into the light emitting layer, which will affect the light emitting efficiency. Moreover, special feeding device and evaporation device are required due to high chemical activities of Li and Cs, thus, its manufacturing cost is increased.

### SUMMARY

Embodiments of the present invention provide an organic electroluminescence device and a display apparatus, in which electron injection capability and electron transport capability are improved without affecting light emitting efficiency and increasing cost.

In order to achieving the purposes mentioned above, embodiments of the present invention provide the following technical solutions:

An organic electroluminescence device, comprising an anode, a cathode, and a light emitting layer disposed between the anode and the cathode; the organic electroluminescence device further comprising:

An electron transport layer disposed between the cathode and the light emitting layer, wherein a phthalocyanine dye is doped in the electron transport layer.

For example, doping concentration of the phthalocyanine dye is more than 0% and less than or equal to 70%.

For example, doping concentration of the phthalocyanine dye is greater than or equal to 40% and less than or equal to 60%.

For example, the phthalocyanine dye comprises one or more of CuPc, ZnPc, F₁₆CuPc, CoPe, F₁₆CoPc, TiCl₂Pc and TiOPc.

Host material of the electron transport layer comprises one or more of Bphen, NBphen (2,9-bis(naphthalen-2-yl)-4,7-diphenyl-1,10-phenanthroline) and TPBi (2,2′,2″-(1,3,5-benzinetriyl)-tris(1-phenyl-1-Hbenzimidazole)).

For example, the anode is an ITO (indium tin oxide) layer.

For example, the organic electroluminescence layer further comprises:

A hole transport layer disposed between the anode and the light emitting layer; a hole injection layer disposed between the anode and the hole transport layer; and an electron injection layer disposed between the electron transport layer and the cathode.

For example, the organic electroluminescence layer has a series stacked structure.

Embodiments of the present invention also provide a display apparatus, which comprises the organic electroluminescence device.

Embodiments of the present invention provide an organic electroluminescence layer and a display apparatus, wherein a phthalocyanine dye is doped in an electron transport layer. Thus, electron injection and transport efficiency of OLED are obviously improved, amount of the holes and the electrons in the light emitting layer are balanced, such that light emitting efficiency of the device is obviously improved. Moreover, as the problem of metal diffusion into the light emitting layer will no longer exist, it is unnecessary to modify the manufacturing device, thus, the driving voltage can be effectively decreased and the manufacturing cost is reduced to a certain extent.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a schematic cross-section structure diagram of an organic electroluminescence device according to an embodiment of the present invention;

FIG. 2 is a schematic comparison diagram of voltage-current density-brightness curves of an OLED in which CuPc is doped in an electron transport layer and of a conventional OLED at various driving voltages;

FIG. 3 is a schematic comparison diagram of current density-current efficiency curves of an OLED in which CuPc is doped in an electron transport layer and of a conventional OLED at various current densities;

FIG. 4 is a schematic comparison diagram of voltage-current density-brightness curves of an OLED in which ZnPc is doped in an electron transport layer and of a conventional OLED at various driving voltages; and

FIG. 5 is a schematic comparison diagram of current density-current efficiency curves of an OLED in which ZnPc is doped in an electron transport layer and of a conventional OLED at various current densities.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

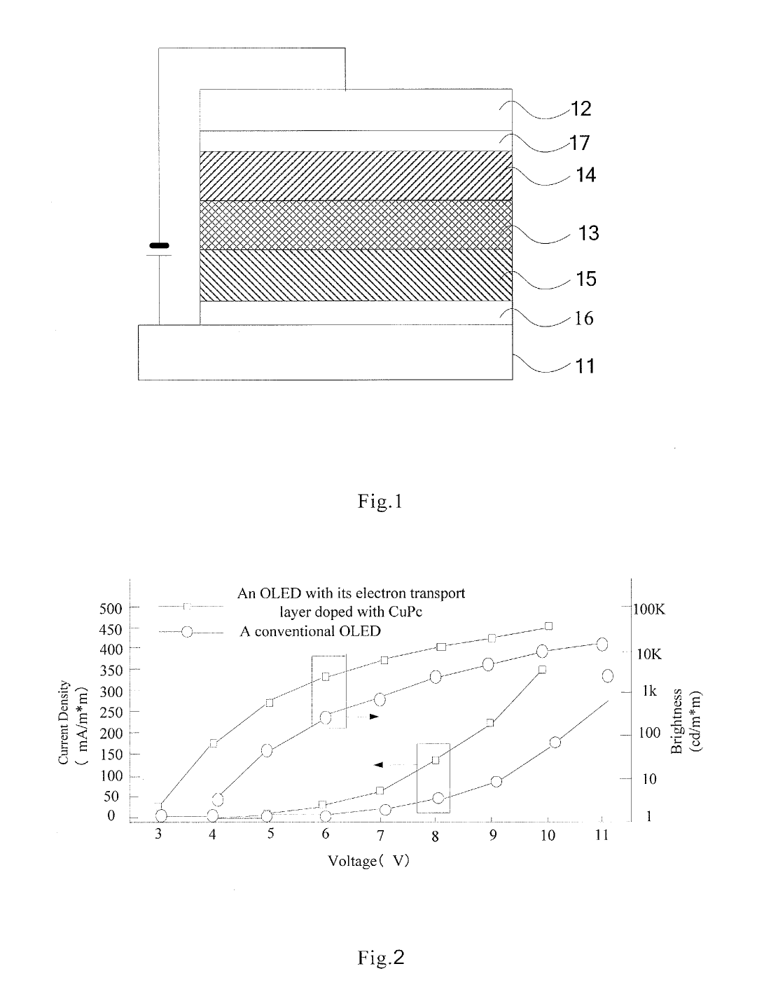

An embodiment of the present invention provides an organic electroluminescence device. As illustrated in FIG. 1, the organic electroluminescence device comprises an anode 11, a cathode 12, and a light emitting layer 13 disposed between the anode 11 and the cathode 12; and an electron transport layer 14 disposed between the cathode 12 and the light emitting layer 13. The electron transport layer 14 is used for transporting electrons generated by the cathode 12 to the light emitting layer 13, and in the embodiment, a phthalocyanine dye is doped in the electron transport layer.

It should be noted here that, the electron transport layer in embodiments of the present invention is a doped material layer comprising a host material and a guest material, wherein the host material of the electron transport layer can be Bphen, which is commonly used in electron transport layer of the conventional technologies, and the guest doping material is a phthalocyanine dye. Embodiments of the present invention will be described by taking Bphen used as the host material for the electron transport layer as an example.

The organic electroluminescence device according to the embodiment of the present invention can obviously improve electron injection and transport efficiency of OLEDs by doping a phthalocyanine dye in the electron transport layer. Further, amount of the holes and the electrons of the light emitting layer is balanced, thus, light emitting efficiency of the device is obviously improved. As there is no metal doping material in the electron transport layer, the technical problem that metal material diffuses into the light emitting layer does not exist any longer, and it is unnecessary to modify manufacturing devices. It is also possible to decrease the driving voltage in a light emitting device in which a phthalocyanine dye is doped in its electron transport layer. Thus, the cost for the device can be reduced to a certain extent.

For example, the doping concentration of the phthalocyanine dye is more than 0% and less than or equal to 70%, which is calculated by a mass percentage of the phthalocyanine dye in the electron transport layer. Herein, the doping concentration refers to a mass percentage.

For example, the doping concentration of the phthalocyanine dye is in a range of 40% to 60%.

For example, the doping concentration of the phthalocyanine dye is 45%.

For example, the phthalocyanine dye comprises CuPc, ZnPc, F₁₆CuPc, CoPe, F₁₆CoPc, TiCl₂Pc, or TiOPc.

For example, the anode is an ITO (Indium Tin Oxides) pattern layer. As the ITO layer used as the anode is patterned and has a rugged surface, light will not be totally reflected at the surface of the anode. Thus, light that would have been total-reflected becomes to be emitted from glass, and light output can be enhanced.

Alternatively, as illustrated in FIG. 1, the organic electroluminescence device further comprises a hole transport layer 15 disposed between the anode 11 and the light emitting layer 13, a hole injection layer 16 disposed between the anode 11 and the hole transport layer 15, and an electron injection layer 17 disposed between the electron transport layer 14 and the cathode 12.

In the embodiment of the present invention, the anode 11 can be a glass substrate with ITO pattern; the hole injection layer 16 can be made of a material such as MoO₃, F_{4—}TCNQ or the like; the hole transport layer 15 can be made of a material such as NPB, TPD or the like; the light emitting layer 13 can be made of a material such as organic large molecule polymer, organic small molecule fluorescent material, organic small molecule phosphorescence material or the like, the light emitting layer can be a light emitting layer which adopts other undoped monocolour, mixing colors and white, and the light emitting layer can also be a light emitting layer that adopts other doped monocolour, mixing colors and white; the electron transport layer 14 can be made of an organic metal chelate compound such as CuPc or the like; the electron injection layer 17 can be made of a common electron injection material, such as LiF, Liq, CsF, Cs₂CO₃ or the like; and the cathode 12 can be made of Al.

For example, if the electron transport layer 14 can not block the holes well, a hole blocking layer can further be disposed between the electron transport layer 14 and the light emitting layer 13 of the organic electroluminescence device.

As an example, in the organic electroluminescence device according to one embodiment of the present invention, each functional layer can be described as follows: the light emitting layer can be a doped blue light emitting layer, doped host material of the blue light emitting layer is MAND (2-methyl-9,10-bis(naphthalen-2-yl) anthracene) and doping guest material of the blue light emitting layer is DSA-Ph (1-4-di-[4-(N,N-diphenyl)amino]styryl-benzene). In the organic electroluminescence device, the anode is an ITO pattern layer with a thickness of 140 nm; the hole injection layer is made of MoO₃ and has a thickness of 5 nm; the hole transport layer is made of NPB and has a thickness of 40 nm; the blue light emitting layer is made of MAND:DSA-Ph and has thickness of 30 nm; the electron transport layer is made of a material which is Bphen doped with CuPc, doping concentration of which is 45%, and has a thickness of 35 nm; the electron injection layer is made of LiF and has a thickness of 1 nm; and the cathode is made of Al and has a thickness of 120 nm.

A method for manufacturing the organic electroluminescence device doped with CuPc is as below: a transparent glass substrate with an ITO layer (its sheet resistance is less than 30Ω/square) is photoetched so as to form an ITO pattern layer, and then the glass substrate with the ITO pattern layer is cleaned sequentially in de-ionized water, acetone, and absolute ethyl alcohol in an ultrasonic environment, after that, the glass substrate is dried by N₂ and is subjected to an O₂ plasma treatment. Finally, the treated substrate is placed in an evaporation chamber at a vacuum less than 5×10⁻⁴ Pa, and a hole injection layer MoO₃ (with a thickness of 5 nm), a hole transport layer NPB (with a thickness of 40 nm), a blue light emitting layer MAND:DSA-Ph (3%) (with a thickness of 30 nm), an electron transport layer Bphen:CuPc (wherein doping concentration of CuPc is 45%) (with a thickness of 30 nm), the electron buffer layer LiF (with a thickness of 1 nm) and a cathode Al (with a thickness of 120 nm) are sequentially deposited on the ITO pattern layer using vacuum thermal evaporation method. In the process of evaporation mentioned above, except that Al is deposited at an evaporation speed of 0.3 nm/s by using a cathode metal mask, other layers are deposited at an evaporation speed of 0.1 nm/s by using an open mask; and light emitting area of the device is 3 mm×3 mm.

Hereinafter, taking an electron transport layer made of Bphen doped with CuPc or ZnPc as an example, it is compared with an electron transport layer made of Bphen in conventional technologies.

Comparison I: An electron transport layer made of Bphen doped with CuPc is compared with an electron transport layer made of Bphen in conventional technologies.

In conventional technologies, an electron transport layer of an organic electroluminescence layer is made of Bphen, and lowest unoccupied molecular orbital (abbreviated as LUMO) energy level of both an cathode (Al) and an electron injection layer (LiF) is about −4.2 eV, LUMO energy level of an electron transport layer (Bphen) is −2.9 eV, LUMO energy level of a light emitting layer (MAND:DSA-Ph) is about −2.5 eV; wherein there is a great energy level difference between the electron transport layer Bphen (−2.9 eV) and the electron injection layer LiF (−4.2 eV) and a large driving voltage is required. While in the organic electroluminescence device according to embodiments of the present invention, CuPc (with an LUMO energy level of −3.6 eV) doped in Bphen of the electron transport layer can reduce the LUMO energy level of the electron transport layer, such that energy level difference between the electron transport layer and the electron injection layer LiF (−4.2 eV) is suitable and the driving voltage is decreased.

On the other hand, electron mobility of CuPc under an electric field of 3.0×10⁵V/cm can be up to 9.04×10⁻⁴ cm²/Vs while electron mobility of the conventional electron transport material Bphen under an electric field of 3.0×10⁵V/cm is 4.2×10^{-4 cm}²/Vs. The electron mobility of CuPc is much greater than the electron mobility of Bphen. That is to say, an organic electroluminescence device utilizing an electron transport layer made of Bphen doped with CuPc has better electron injection and transport efficiency.

The property comparison between the electron transport layer doped with CuPc according to the aforementioned embodiment of the present invention and the electron transport layer provided in conventional technologies will be performed through experimental measurements in the following. Test results shown in Table 1 are obtained from measuring photoelectrical properties of organic electroluminescence device with various doping concentration of CuPc. Normally, the organic electroluminescence device with brightness over 1000 cd/m² can meet requirements in performance. Generally, the performance of the organic electroluminescence device is indicated by its maximal current efficiency. It can be seen from Table 1 that the organic electroluminescence device in which the electron transport layer is doped with CuPc (doping concentration of CuPc being 10%, 20%, . . . , 70%) has a better performance than an organic electroluminescence layer in which its electron transport layer undoped with CuPc (the doping concentration of CuPc being 0%), and the organic electroluminescence device has a maximal current efficiency and has best performance when doping concentration of CuPc is 45%.

TABLE 1

| Doping | Current | Maximal | |
|---|---|---|---|
| Concentration | Density at 8 V | Brightness | Maximal Current |
| of CuPc ( wt % ) | ( mA/cm² ) | ( cd/m² ) | Efficiency (cd/A) |
| 0 | 91.85 | 26700 | 8.98 |
| 10 | 101.13 | 29680 | 9.72 |
| 20 | 116.96 | 34750 | 11.2 |
| 30 | 116.38 | 39400 | 13.7 |
| 40 | 132.71 | 45420 | 15.13 |
| 45 | 151.74 | 53170 | 15.9 |
| 50 | 145.14 | 54140 | 13.92 |
| 60 | 142.25 | 41070 | 13.26 |
| 70 | 136.94 | 38720 | 12.38 |

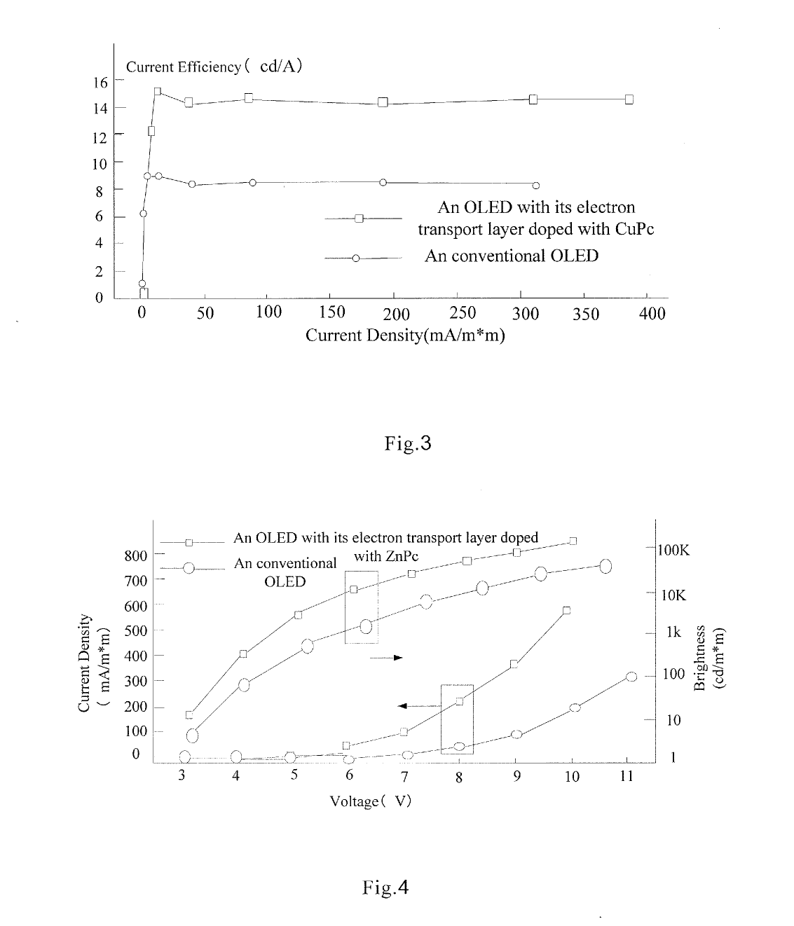

FIG. 2 and FIG. 3 illustrate comparisons in performances of the organic electroluminescence device with doping concentration of CuPc being 45% according to the embodiment of the present invention and an organic electroluminescence device in conventional technologies, wherein FIG. 2 illustrates voltage-current density curve diagram and voltage-brightness curve diagram of the two organic electroluminescence devices at various driving voltages. FIG. 3 illustrates current density-current efficiency curve diagram of the two organic electroluminescence devices at various current densities. It can be seen from the figures that, compared to a conventional organic electroluminescence devices utilizing an electron transport layer made of Bphen, the organic electroluminescence device according to the embodiment of the present invention utilizes an electron transport layer made of Bphen doped with CuPc, and its current density and brightness is improved obviously, indicating that electron injection capability of the organic electroluminescence device is significantly improved. The maximal brightness of the organic electroluminescence device is increased from 26700 cd/m² to 53170 cd/m², with an increasing rate of approximately 99.2%, and the maximal current efficiency is increased from 8.98 cd/A to 15.9 cd/A, with an increasing rate of approximately 65.9%. It can be seen from above that light emitting property of the organic electroluminescence device utilizing an electron transport layer made of Bphen doped with CuPc is greatly improved relative to a conventional organic electroluminescence device utilizing an electron transport layer made of Bphen.

Comparison II: An electron transport layer made of Bphen doped with ZnPc is compared with an electron transport layer made of Bphen in conventional technologies.

The embodiment of the present invention provides an organic electroluminescence device utilizing an electron transport layer made of Bphen doped with ZnPc. Except that material for the electron transport layer is different, material and thickness of other functional layers are the same with corresponding functional layers of the organic electroluminescence device utilizing an electron transport layer made of Bphen doped with CuPc.

LUMO energy level of ZnPc doped into Bphen (−2.9 eV) of the electron transport layer is −3.3 eV. LUMO energy level of the electron transport layer can also be decreased, such that difference of energy level between the electron transport layer and the electron injection layer LiF (−4.2 eV) is suitable and facilitates to reduce driving voltage.

Test results shown in Table 2 are obtained by measuring photoelectrical properties of organic electroluminescence device with various doping concentration of ZnPc. Normally, the organic electroluminescence device with brightness over 1000 cd/m² can meet requirements in performance. Generally, the performance of the organic electroluminescence device is indicated by its maximal current efficiency. It can be seen from Table 2 that the organic electroluminescence device in which the electron transport layer is doped with ZnPc (doping concentration of CuPc being 10%, 20%, . . . , 70%) has a better performance than an organic electroluminescence layer in which its electron transport layer is not doped with ZnPc (the doping concentration of ZnPc being 0%), and the organic electroluminescence device has a maximal current efficiency and has best performance when doping concentration of CuPc is 45%.

TABLE 2

| Doping | | Maximal | |
|---|---|---|---|
| Concentration | Current Density | Brightness | Maximal Current |
| of ZnPc ( wt % ) | at 8 V ( mA/cm² ) | ( cd/m² ) | Efficiency (cd/A) |
| 0 | 90.76 | 17800 | 8.96 |
| 10 | 97.15 | 28150 | 9.16 |
| 20 | 103.14 | 31900 | 10.77 |
| 30 | 117.39 | 37450 | 12.13 |
| 40 | 129.86 | 41600 | 13.11 |
| 45 | 135.29 | 43170 | 13.4 |
| 50 | 216.87 | 44500 | 13.02 |
| 60 | 207.68 | 42870 | 12.86 |
| 70 | 195.21 | 40510 | 12.6 |

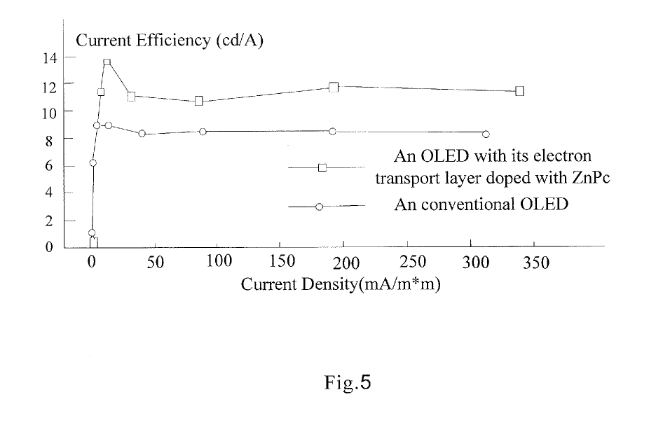

FIG. 4 and FIG. 5 illustrate comparison in performances of the organic electroluminescence device with doping concentration of ZnPc being 45% according to the embodiment of the present invention and an organic electroluminescence device in conventional technologies. FIG. 4 illustrates voltage-current density curve diagram and voltage-brightness curve diagram of the two organic electroluminescence devices at various driving voltages. FIG. 5 illustrates current density-current efficiency curve diagram of the two organic electroluminescence devices at various current densities. It can be seen from FIG. 4 and FIG. 5 that, compared to a conventional organic electroluminescence device utilizing an electron transport layer made of Bphen, light emitting property of the organic electroluminescence device utilizing an electron transport layer made of Bphen doped with ZnPc is significantly improved.

Test results shown that, if an electron transport layer is made of Bphen doped with other phthalocyanine dyes, electron mobility of an organic electroluminescence device comprising the electron transport layer can also be greatly improved. The phthalocyanine dyes comprise one or more of CuPc, ZnPc, F₁₆CuPc, CoPc, F₁₆CoPc, TiCl₂Pc and TiOPc.

Hereinbefore, it is described that current efficiency of an electron transport layer doped with phthalocyanine dyes is greatly improved and the photoelectrical properties and the light emitting efficiency are improved by taking Bphen as host material in an electron transport layer as an example. It can be understood by those skilled in the art that, if phthalocyanine dyes are doped into other material which is used as the host material for an electron transport layer, the electron mobility of an organic electroluminescence device comprising the electron transport layer can also be significantly improved. Materials that can be used as the host material for the electron transport layer comprise one or more of Bphen, NBphen (2,9-bis(naphthalen-2-yl)-4,7-diphenyl-1,10-phenanthroline) and TPBi (2,2′,2″-(1,3,5-benzinetriyl)-tris(1-phenyl-1-Hbenzimidazole)).

The organic electroluminescence device according to the embodiments of the present invention can further utilize a series stacked structure. In the organic electroluminescence device with series stacked structure, a plurality of devices are connected in series through common anodes and common cathodes. Thus, light emitting efficiency of the organic electroluminescence device can be improved and life of the device can be elongated.

Embodiments of the present invention provide a display apparatus which comprises the organic electroluminescence device as described above. The display apparatus can be any product or component that has a displaying function, such as an OLED display apparatus, an OLED display panel, a digital frame, a cell phone, a tablet PC or an electric paper display apparatus.

What are described above is related to the illustrative embodiments of the disclosure only and not limitative to the scope of the disclosure; the scopes of the disclosure are defined by the accompanying claims.

1. An organic electroluminescence device comprising an anode, a cathode and a light emitting layer disposed between the anode and the cathode; wherein the organic electroluminescence device further comprising:
an electron transport layer disposed between the cathode and the light emitting layer, wherein the electron transport layer is doped with a phthalocyanine dye.

2. The organic electroluminescence device according to claim 1, wherein mass percentage concentration of the phthalocyanine dye in the electron transport layer is more than 0% and less than or equal to 70%.

3. The organic electroluminescence device according to claim 2, wherein the mass percentage concentration of the phthalocyanine dye in the electron transport layer is more than or equal to 40%, and less than or equal to 60%.

4. The organic electroluminescence device according to claim 1, wherein the phthalocyanine dye comprises one or more of CuPc, ZnPc, F₁₆CuPc, CoPc, F₁₆CoPc, TiCl₂Pc and TiOPc.

5. The organic electroluminescence device according to claim 1, wherein a host material of the electron transport layer comprises one or more of Bphen, NBphen and TPBi.

6. The organic electroluminescence device according to claim 1, wherein the anode is an ITO pattern layer.

7. The organic electroluminescence device according to claim 1, further comprising:
a hole transport layer disposed between the anode and the light emitting layer; a hole injection layer disposed between the anode and the hole transport layer; and an electron injection layer disposed between the electron transport layer and the cathode.

8. The organic electroluminescence device according to claim 1, wherein the organic electroluminescence device has a series stacked structure.

9. A display apparatus comprising the organic electroluminescence device according to claim 1.

10. The organic electroluminescence device according to claim 2, wherein the phthalocyanine dye comprises one or more of CuPc, ZnPc, F₁₆CuPc, CoPc, F₁₆CoPc, TiCl₂Pc and TiOPc.

11. The organic electroluminescence device according to claim 2, wherein a host material of the electron transport layer comprises one or more of Bphen, NBphen and TPBi.

12. The organic electroluminescence device according to claim 4, wherein a host material of the electron transport layer comprises one or more of Bphen, NBphen and TPBi.

13. The organic electroluminescence device according to claim 10, wherein a host material of the electron transport layer comprises one or more of Bphen, NBphen and TPBi.

14. The organic electroluminescence device according to claim 2, wherein the anode is an ITO pattern layer.

15. The organic electroluminescence device according to claim 4, wherein the anode is an ITO pattern layer.

16. The organic electroluminescence device according to claim 5, wherein the anode is an ITO pattern layer.

17. The organic electroluminescence device according to claim 2, further comprising:
a hole transport layer disposed between the anode and the light emitting layer; a hole injection layer disposed between the anode and the hole transport layer; and an electron injection layer disposed between the electron transport layer and the cathode.

18. The organic electroluminescence device according to claim 4, further comprising:
a hole transport layer disposed between the anode and the light emitting layer; a hole injection layer disposed between the anode and the hole transport layer; and an electron injection layer disposed between the electron transport layer and the cathode.

19. The organic electroluminescence device according to claim 5, further comprising:
a hole transport layer disposed between the anode and the light emitting layer; a hole injection layer disposed between the anode and the hole transport layer; and an electron injection layer disposed between the electron transport layer and the cathode.

20. The organic electroluminescence device according to claim 6, further comprising:
a hole transport layer disposed between the anode and the light emitting layer; a hole injection layer disposed between the anode and the hole transport layer; and an electron injection layer disposed between the electron transport layer and the cathode.
